(19) United States
(12) Patent Application Publication
(10) Pub. No.: US 2004/0057545 A1
(43) Pub. Date: Mar. 25, 2004

(54) Data reading method, data reading apparatus, and data reading program

(75) Inventor: Yukio Hayashi, Tokyo-to (JP)

Correspondence Address: MORGAN LEWIS & BOCKIUS LLP, 1111 PENNSYLVANIA AVENUE NW, WASHINGTON, DC, 20004, US

(73) Assignee: PIONEER CORPORATION

(21) Appl. No.: 10/664,897

(22) Filed: Sep. 22, 2003

(30) Foreign Application Priority Data
Sep. 20, 2002 (JP) P2002-274694

(51) Int. Cl. H04L 7/00; G06K 9/36; H03M 7/40

(52) U.S. Cl. 375/368; 382/246; 341/67

(57) ABSTRACT

A data reading apparatus reads variable length-coded data. A digital signal processor of this data reading apparatus executes a code word reading step of sequentially reading a series of code words partitioned by a plurality of resynchronization markers, and a resynchronization marker detecting step of detecting a next resynchronization marker before a reading position in the code word reading step reaches the next resynchronization marker.

### BACKGROUND OF THE INVENTION

1. Field of the Invention

The present invention relates to a data reading method and the like for reading variable length-coded (VLC) data.

2. Description of the Related Art

There is a coding technique of coding a plurality of events according to a fixed length code to express each of the events by using code words of the same length. In decoding data that uses the fixed length code, even when there occurs an error in a bit series, a header position of a code word after the error can be known. Therefore, data after the error position can be decoded normally.

On the other hand, there is known a method of coding a plurality of events according to a variable length code by allocating code words of different lengths to the events. When a variable length code is used, it is possible to change the length of a code word by considering the appearance frequency. Therefore, there is an advantage of being able to decrease a total data quantity.

However, when the variable length code is used, a header position of a succeeding code word becomes unknown when there is an error. Therefore, in principle, code words positioned after the error cannot be decoded in a chain.

### SUMMARY OF THE INVENTION

It is an object of the present invention to provide a data reading method, a data reading apparatus and the like capable of decreasing the influence of an error in reading variable length-coded data.

In order to realize the above object, as one aspect, the present invention provides a data reading method of reading variable length-coded data, the method comprising: a first code word reading step of sequentially reading a series of code words partitioned by a plurality of resynchronization markers; and a resynchronization marker detecting step of detecting a next resynchronization marker before a reading position in the first code word reading step reaches the next resynchronization marker.

In order to realize the above object, as another aspect, the present invention provides a data reading apparatus for reading variable length-coded data, comprising: a first code word reading device for sequentially reading a series of code words partitioned by a plurality of resynchronization markers; and a resynchronization marker detecting device for detecting a next resynchronization marker before a reading position by the first code word reading device reaches the next resynchronization marker.

In order to realize the above object, as further aspect, the present invention provides a program for executing a data reading method of reading variable length-coded data, wherein the programs makes a computer function as: a first code word reading step of sequentially reading a series of code words partitioned by a plurality of resynchronization markers; and a resynchronization marker detecting step of detecting a next resynchronization marker before a reading position in the first code word reading step reaches the next resynchronization marker.

### BRIEF DESCRIPTION OF THE DRAWINGS

FIG. 1 is a block diagram of a structure of a data reading apparatus that executes a data reading method according to an embodiment of the present invention;

FIG. 2 is an exemplification of a variable length code;

FIG. 3A is a conceptual diagram of insertion positions of resynchronization markers in a bit series of video data, and FIG. 3B is a conceptual diagram of insertion positions of resynchronization markers in a video;

FIG. 4 is an exemplification of a code word and a bit series;

FIG. 5 is a flowchart of a data reading step;

FIGS. 6A to 6C are exemplifications of decoding results according to a conventional decoding method respectively;

FIG. 7 is an exemplification of a reversible variable length code (RVLC) structured to be able to be decoded in a reverse direction; and

FIG. 8 is a comparative diagram of a readable data range according to a data reading method of the present embodiment and according to a conventional data reading method.

### DESCRIPTION OF THE PREFERRED EMBODIMENTS

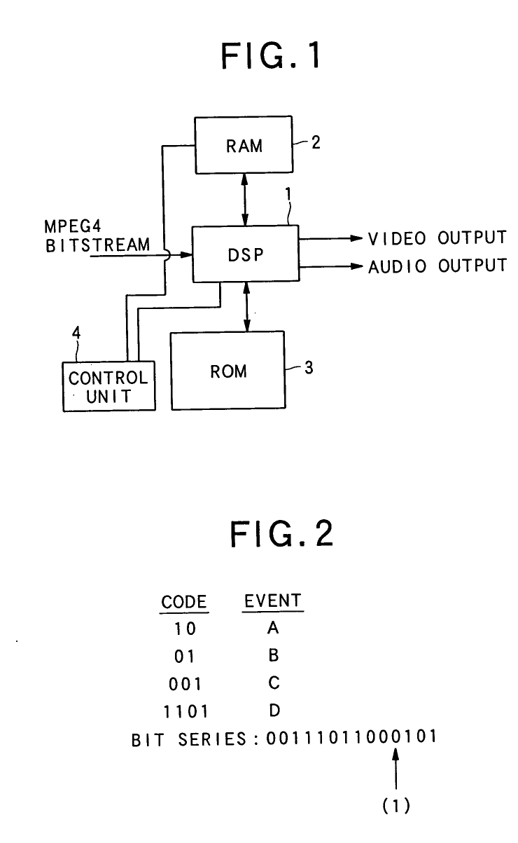

A data reading method according to the present invention will be explained with reference to FIG. 1 to FIG. 8. FIG. 1 is a block diagram of a structure of a data reading apparatus that executes a data reading method according to an embodiment of the present invention.

As shown in FIG. 1, the data reading apparatus comprises a digital signal processor (DSP) 1 that decodes a bitstream according to the MPEG4 thereby to generate a video signal and an audio signal, a random access memory (RAM) 2 that sequentially stores data necessary for the DSP 1 to process the data, a read only memory (ROM) 3 that stores a program such as a decoding program or the like for prescribing the processing carried out by the DSP 1 and a control unit 4, and the control unit 4 that controls the DSP 1, the RAM 2, and the ROM 3.

The bitstream input to the DSP 1 will be explained next. In the present embodiment, the bitstream uses a bit series generated according to a variable length coding following the MPEG4. The variable length coding system allocates code words having different lengths to an event to be coded such as the alphabet a, b, c, etc., for example. With this arrangement, an event of high appearance frequency can be expressed by using short code words, and an event of low appearance frequency can be expressed by using long code words. As a result, the bit series can be shortened in total.

FIG. 2 is an exemplification of a variable length code. In the example shown in FIG. 2, a code word “10” denotes an English letter “A”, a code word “01” denotes an English letter “B”, a code word “001” denotes an English letter “C”, and a code word “1101” denotes an English letter “D”. In this case, when the bit series is “00111011000101” as shown in FIG. 2, this bit series is decoded as “CDACB”. On the other hand, when a bit at a position (1) of the bit series is inverted by error, the bit series is decoded as “CDAX”. “X” denotes that an inconvertible code word not in the table is detected (hereinafter, X denotes the same). After a variable length coding, a starting position of a code following “X” is not clear. Therefore, it is not possible to decode a series of code words after “X”.

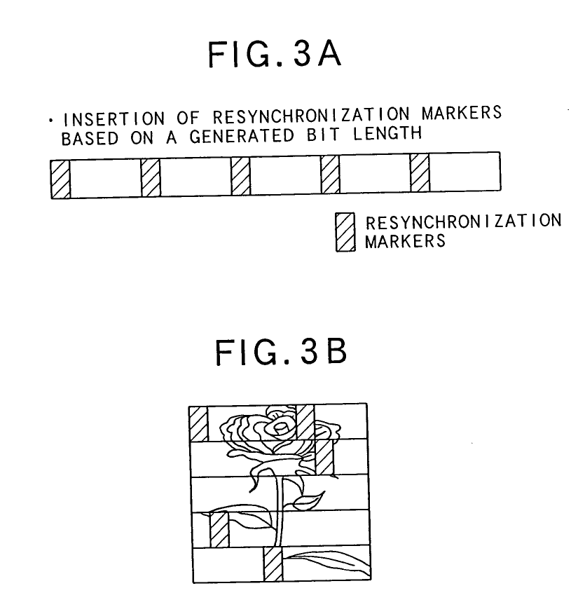

In order to solve the above drawbacks of the variable length coding, re-synchronization markers are inserted into the bit series. FIGS. 3A and 3B are conceptual diagrams of an insertion position of a resynchronization marker. As shown in FIGS. 3A and 3B, a plurality of resynchronization markers are inserted into the middle of video data. In this example, each time when a generation bit length reaches a predetermined length, a resynchronization marker is inserted within a video object plane (VOP) that constitutes one frame. FIG. 3A is a conceptual diagram of insertion positions of resynchronization markers in a bit series of video data, and FIG. 3B is a conceptual diagram of insertion positions of resynchronization markers in video data sequentially corresponding to pixels from a left top position to a right down position.

By inserting the resynchronization markers in this way, it is possible to identify a decoding starting point, that is, a starting position of a header code word. A unit between the resynchronization markers is called a video packet. Information necessary to start decoding again is described in the header portion of the video packet. A coding information portion that follows the header portion can store code words (i.e., macro block coding information) corresponding to an optional number of events. A bitstream corresponding to one VOP can be divided into an optional number of video packets.

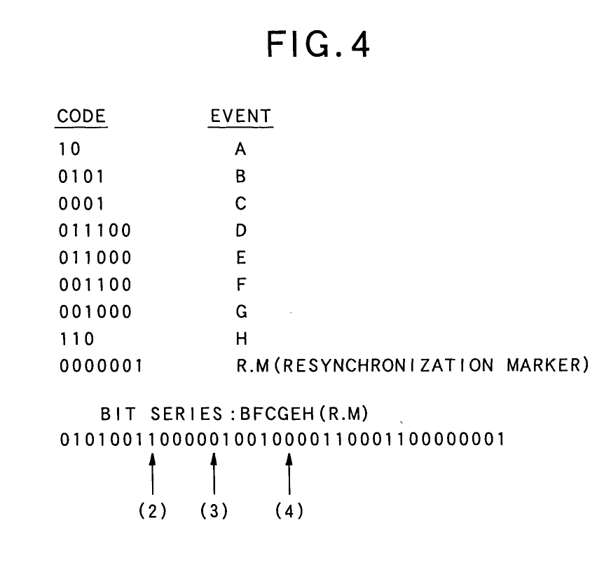

FIG. 4 is an exemplification of code words that identify “resynchronization markers” of “A”, “B”, “C”, “D”, “E”, “F”, “G”, and “H”, and a bit series that sequentially identifies “resynchronization markers of B, F, C, G, E, and H”. As shown in FIG. 4, data are sequentially read from the header, and each time when a code word allocated with an event is detected, the code word is decoded sequentially.

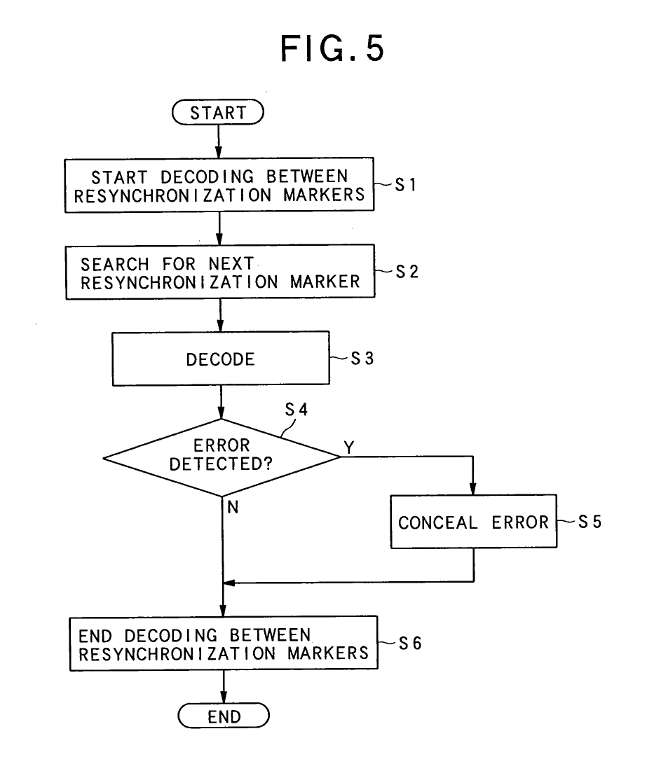

The operation of a data reading apparatus will be explained below with reference to FIG. 5 to FIG. 7. FIG. 5 is a flowchart of a data reading step. The control unit 4 controls the processing shown in FIG. 5 by using a program stored in the ROM 3.

At step S1 in FIG. 5, the data reading apparatus reads data of a predetermined packet partitioned by a resynchronization marker, and starts decoding the video packet. Next, the data reading apparatus searches for the next resynchronization marker positioned between the video packet currently decoded and the next video packet (step S2). After detecting the next resynchronization marker, the data reading apparatus decodes the current video packet (step S3), and judges whether an error is detected in the decode processing (step S4). When a decision is YES, the process proceeds to step S5, and when a decision is NO, the process proceeds to step S6. At step S5, the data reading apparatus conceals the error that coincides with the detected error contents, and proceeds to step S6. At step S6, the data reading apparatus ends decoding the corresponding VOP. By repeating the above processing for each video packet, it is possible to sequentially execute the decoding.

In the error detection processing at step S5, the data reading apparatus can identify an error in a read code word when the read code word is not in the table or when an unsuitable value (i.e., value appearing only in error) is found.

In the present embodiment, the data reading apparatus may read the information concerning the number of data bits included in the video packet between the resynchronization markers (for example, a maximum number of bits included in the video packet) from the header portion, and carries out the processing by using this information. For example, when the next resynchronization marker cannot be detected even when the number exceeds a number of bits that should be included in the video packet, it becomes clear at this time when the bit is inverted at the resynchronization marker position. Therefore, the data reading apparatus can promptly execute a proper processing. Further, when decoding of the code words does not end even when the number exceeds the number of bits that should be included in the video packet, it is possible to identify an error.

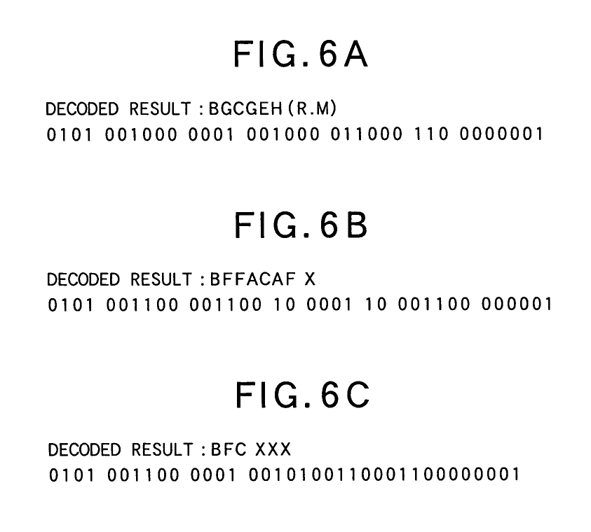

A result of the decoding processing shown in FIG. 5 will be explained by comparing it with the conventional method. FIGS. 6A to 6C are exemplifications of decoding results according to the conventional decoding method respectively.

When a bit at a position (2) of the bit series shown in FIG. 4 is inverted by error, the bit series is decoded in the order of “resynchronization markers B, G, C, G, E, and H” according to the conventional method, as shown in FIG. 6A. In the present embodiment, while the next resynchronization marker is detected in advance, a decoding result that is the same as that according to the conventional decoding method is obtained.

When a bit at a position (3) of the bit series shown in FIG. 4 is inverted by error, the bit series is decoded in the order of “B, F, F, A, C, A, F, and X” according to the conventional method, as shown in FIG. 6B. Accordingly, it is not possible to detect the next resynchronization marker. Consequently, the next video packet cannot be decoded normally. On the other hand, according to the present embodiment, the next resynchronization marker can be detected securely even when this bit reversal occurs. Therefore, it is possible to decode the next video packet starting from the header of this packet.

When a bit at a position (4) of the bit series shown in FIG. 4 is inverted by error, the bit series is decoded in the order of “B, F, C, X, X, and X” according to the conventional method, as shown in FIG. 6C. At the moment when a code word that cannot be decoded appears, detection of the next resynchronization marker is started. According to the present embodiment, while the next resynchronization marker is detected in advance, it is possible to obtain a decoding result that is the same as that obtained according to the conventional decoding method as a result.

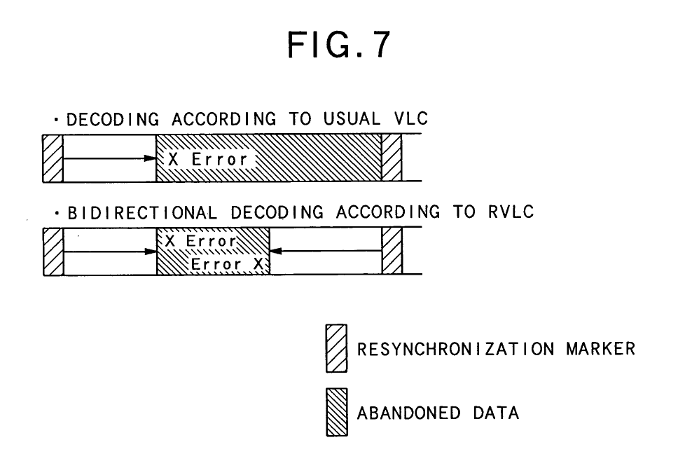

FIG. 7 is an exemplification of a reversible variable length code (RVLC) specially structured to be able to be decoded in a reverse direction for reading as well. As shown in FIG. 7, when a code is a usual variable length code that can be decoded from only one direction, data at a position after the occurrence of an error cannot be decoded. Consequently, these data cannot be utilized. On the other hand, when data can be decoded in both a forward direction and a reverse direction for reading, a range of data that cannot be utilized is limited to only a portion that is not included in either a range of data that can be decoded in the forward direction or a range of data that can be decoded in the reverse direction. Therefore, the data can be utilized more effectively than the data according to the usual variable length code. The variable length code also decodable in the reverse direction can be applied to the data reading method according to the present invention.

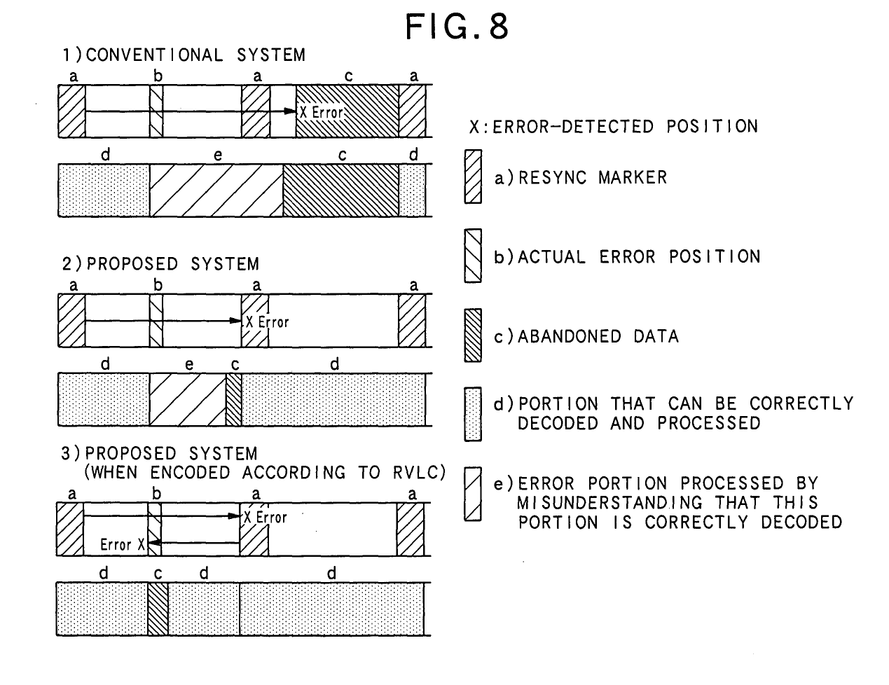

FIG. 8 is a comparative diagram of a readable data range according to the data reading method of the present embodiment and according to the conventional data reading method. As shown in FIG. 8, according to the conventional method (i.e., the conventional method (1) in FIG. 8), there is a possibility that even when there is an error between an actual error position (b) and a position (X) where the error is detected, a portion (e) that is decided as being correctly decoded continues to the next video packet. In other words, when the next resynchronization marker (a) is included in the erroneously decoded portion (e), data in the next video packet is decoded erroneously. This means the occurrence of a phenomenon that the error propagates to the next video packet. In the example shown in FIG. 8, data is abandoned starting from a position slightly before the error-detected position (X) (for example, a position before a length corresponding to the last code word). This similarly applies to the explanation of the present embodiment in FIG. 8.

On the other hand, according to the data reading method of the present embodiment, when a usual variable length coding method is used (i.e. a proposed system (2) in FIG. 8), the next resynchronization marker (a) is detected in advance. Therefore, a byte length (a bit length) between the resynchronization markers is known in advance. In other words, a byte length or a bit length of the video packet is known in advance. Accordingly, when the resynchronization marker (a) cannot be recognized when the decoding proceeds to this marker, a contradiction occurs between a decoded byte (or bit) length and a value of this portion. As a result, the presence of the error is identified. In other words, a position of the error within the video packet can be known, and the next video packet can be decoded correctly. Consequently, the next video packet becomes a portion (d) that can be decoded correctly. Further, the portion (e) erroneously decided as being correctly decoded and a data abandoned portion (c) decrease. In other words, based on the identification of an error, a portion that needs not be decoded decreases. This means that there is no risk of the error propagating to the next video packet.

Further, when the data reading method according to the present embodiment employs a variable length coding of data that can be decoded in both the forward and reverse directions (i.e., a proposed system in (3) in FIG. 8), the resynchronization markers are detected. Therefore, it is also possible to decode the data in the reverse direction starting from the detected resynchronization marker. This makes it possible to decode in both directions, and can localize the influence of an error. As a result, the reproduction quality of video or the like further improves. According to the conventional method, next resynchronization markers are not known in advance. Therefore, data cannot be decoded in both directions, and it is not possible to obtain the same effects as those according to the present embodiment.

In the present embodiment, in order to facilitate the visual understanding of the algorithm according to the present embodiment, error occurrence positions, decodable portions, and undecodable portions are disposed as an example in FIG. 8. The processing step according to the present embodiment is not limited to that shown in FIG. 8.

The entire disclosure of Japanese Patent Application No. 2002-274694 filed on Sep. 20, 2002 including the specification, claims, drawings and summary is incorporated herein by reference in its entirety.

What is claimed is:

1. A data reading method of reading variable length-coded data, the method comprising:
a first code word reading step of sequentially reading a series of code words partitioned by a plurality of resynchronization markers; and
a resynchronization marker detecting step of detecting a next resynchronization marker before a reading position in the first code word reading step reaches the next resynchronization marker.

2. The data reading method according to claim 1, further comprising:
a second code word reading step of sequentially reading the series of code words based on the next resynchronization marker detected in the resynchronization marker detecting step.

3. The data reading method according to claim 1, wherein
the data is configured to be read in both forward and reverse directions,
the method further comprises a third code word reading step of reading the series of code words in an opposite direction to a reading direction in the first code word reading step, and
in the third code word reading step, the series of code words are sequentially read based on the resynchronization marker detected in the resynchronization marker detecting step.

4. The data reading method according to claim 1, further comprising:
an error identifying step of identifying an error in a range of data read in the first code word reading step.

5. The data reading method according to claim 4, wherein
in the error identifying step, the error identification is made when the code word read in the first code word reading step is undecodable.

6. The data reading method according to claim 4, further comprising:
a bit number information reading step of reading information about a number of bits between resynchronization markers; and
a counting step of counting the number of bits of a code word read in the first code word reading step, wherein
in the error identifying step, the error identification is made based on the information read in the bit number information reading step and the number of bits counted in the counting step.

7. A data reading apparatus for reading variable length-coded data, comprising:
a first code word reading device for sequentially reading a series of code words partitioned by a plurality of resynchronization markers; and
a resynchronization marker detecting device for detecting a next resynchronization marker before a reading position by the first code word reading device reaches the next resynchronization marker.

8. The data reading apparatus according to claim 7, further comprising:
a second code word reading device that sequentially reads the series of code words based on the next resynchronization marker detected by the resynchronization marker detecting device.

9. A program for-executing a data reading method of reading variable length-coded data, wherein the programs makes a computer function as:
a first code word reading step of sequentially reading a series of code words partitioned by a plurality of resynchronization markers; and
a resynchronization marker detecting step of detecting a next resynchronization marker before a reading position in the first code word reading step reaches the next resynchronization marker.

10. The program according to claim 9, wherein the program makes the computer further function as:
a second code word reading step of sequentially reading the series of code words based on the next resynchronization marker detected in the resynchronization marker detecting step.
